(19) United States
(12) Patent Application Publication
(10) Pub. No.: US 2006/0034057 A1
(43) Pub. Date: Feb. 16, 2006

(54) Clamper for mounting a heatsink

(75) Inventor: Chien-lung Yang, Dayuan Township (TW)

Correspondence Address: APEX JURIS, PLLC, 13194 EDGEWATER LANE NORTHEAST, SEATTLE, WA, 98125, US

(73) Assignee: Mitac Precision Technology, Gueishan Township (TW)

(21) Appl. No.: 10/915,846

(22) Filed: Aug. 11, 2004

(51) Int. Cl. H05K 7/20

(52) U.S. Cl. 361/704

(57) ABSTRACT

A heatsink clamper includes a buckle piece and a main body. The buckle piece includes a latch member buckled to a side of a seat that mounts the heatsink and the hot element of an electronic device, and a press member one end pivoted on an end of the latch member and another end includes a latch end correspondent to the latch portion of the latch member. The latch member includes a latch portion and a raised end. The main body includes a buckle latched to another side of the seat, and a pressing arm linked together included a hole correspondent to the raised end for passing through the raised end and moving relatively. When pressing the press member to move the latch end into the latch portion, the pressing arm is also pressed and deformed to provide a pressure to the heatsink through a receptacle groove.

### FIELD OF THE INVENTION

The invention relates to a clamper applicable to a heatsink of an electronic device. It enables the heatsink stably mounted to the hot member of the electronic device and dissipating the heat.

### BACKGROUND OF THE INVENTION

The operating temperature of electronic components in an electronic device affects the functions of the electronic device. Therefore, in order to keep the electronic device stably operates, there is usually some heat dissipating and cooling apparatuses in the electronic device. In operation, the central processing unit (CPU) in the electronic device generates more heat. Therefore, the operating temperature of the central processing unit is usually the highest portion and requires the most heat dissipation demand.

At present, the cooling for a central processing unit is to mount a heatsink on the central processing unit, and to mount a cooling fan on the heatsink. The operation heat is transmitted from the central processing unit to the heatsink, then, dissipated through the air expelled by the cooling fan to pass through the heatsink and carry the heat away. In the above cooling device, the fitting condition of the heatsink and the central processing unit significantly affects the thermal transmission. Therefore, they have to be closely fitted for an effective heat transfer. Presently the heatsink and the central processing unit are two separate components fastened by a buckle. Most of the prior assembly methods are using a U-shape buckle having two holes at the ends that are connected with hooks formed on sides of a holder for the central processing unit (or for the heatsink). The U-shape buckle crosses downward with a pressure to fit the heatsink and the central processing unit tightly after user serves with a certain force to let the holes of the U-shape buckle fitted into the hooks. Although such device can provide the heatsink a certain pressure, the installation for the user is not easy to achieve. Moreover, the user possibly applies an improper or uneven force to damage the central processing unit or the circuit board of the central processing unit.

### SUMMARY OF THE INVENTION

The object of the invention is to provide a heatsink clamper that is easy to assemble the heatsink to an electronic device, and to dismantle the heatsink from the electronic device.

A heatsink clamper according to the invention includes a buckle piece and a main body. The buckle piece includes a latch member and a press member. The latch member is buckled to a side of a seat that mounts the heatsink and the hot element of the electronic device. The latch member includes a latch portion and a raised end. One end of the press member is pivoted on an end of the latch member. Another end of the press member includes a latch end correspondent to the latch portion of the latch member. The main body includes a buckle and a pressing arm linked together. The buckle is latched to another side of the seat. The pressing arm includes a hole correspondent to the raised end for passing through the raised end and moving relatively. When pressing the press member to move the latch end into the latch portion, the pressing arm is also pressed and deformed to provide a pressure to the heatsink through a receptacle groove and firmly fix the heatsink to the hot element of the electronic device.

When assembly, latch the buckle holes of the buckle piece to the fastening portions on a side the seat. Then, latch the holes of the buckle of the main body to the fastening portions on another side of the seat, so that the pressing arm passes through the receptacle groove of the heatsink, and the hole on the end of the pressing arm passes through the raised end and moves relatively. Finally, lever the press member to move the pressing end of the press member toward the pressed portion, and lock the latch end in the latch portion by the resilient force of the lever end so as to complete the heatsink clamper assembly. The pressing arm provides a downward pressure via the receptacle groove to the base of the heatsink. The heatsink is therefore firmly fastened to the hot element of the electronic device.

Reversedly, when disassembling the clamper from the heatsink, press the lever end to release the latch end from the latch portion by its own resilience, so that the pressing end is released from pressing the pressed portion. Simultaneously, the pressing arm retrieves to its primary form and no longer presses the heatsink. Then, remove the pressed portion of the main body from the raised end of the latch member, and remove the pressing arm from the receptacle groove of the heatsink. Further, remove the buckle holes of the main body from the fastening portions of the seat, and remove the main body from the side of the seat. Finally, remove the buckle piece by releasing the latch member from the other side of the seat, and finish the disassembly.

### BRIEF DESCRIPTION OF THE DRAWINGS

The invention will become more fully understood from the detailed description given hereinbelow. However, this description is for purposes of illustration only, and thus is not limitative of the invention, wherein:

FIG. 1 is an exploded view of a first embodiment of the invention;

FIG. 2 is an assembly drawing of a first embodiment of the invention;

FIGS. 3A, 3B, 3C and 3D are sequential views of assembling or disassembling a first embodiment of the invention;

FIGS. 4A and 4B are functional drawings respectively of a pressing arm that presses and does not press a heatsink in a first embodiment of the invention;

FIG. 5 is an assembly drawing of a second embodiment of the invention in a first angle;

FIG. 6 is an assembly drawing of a second embodiment of the invention in a second angle;

FIGS. 7A, 7B, 7C and 7D are sequential views of assembling or disassembling a second embodiment of the invention;

FIGS. 8A and 8B are functional drawings respectively of a pressing arm that presses and does not press a heatsink in a second embodiment of the invention;

FIG. 9 is an assembly drawing of a third embodiment of the invention in a first angle;

FIG. 10 is an assembly drawing of a third embodiment of the invention in a second angle;

FIGS. 11A, 11B, 11C and 11D are sequential views of assembling or disassembling a third embodiment of the invention; and

FIGS. 12A and 12B are functional drawings respectively of a pressing arm that presses and does not press a heatsink in a third embodiment of the invention.

### DETAILED DESCRIPTION OF THE INVENTION

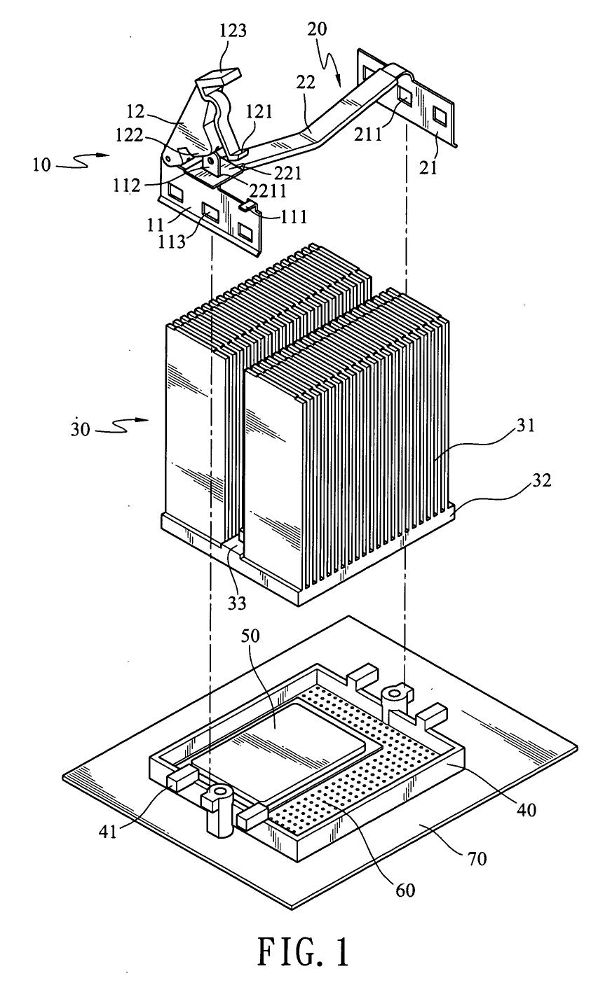

FIG. 1 shows an exploded view of a first embodiment of the invention. The seat 40 is a frame encircling a space to receive a hot element, such as a central processing unit 50, of an electronic device. The central processing unit 50 is connected through connectors 60 to a circuit board 70. The seat 40 is formed with a plurality of fastening portions 41. The heatsink 30 is mounted on top of the central processing unit 50 for dissipating the heat generated by the central processing unit 50. The heatsink 30 includes a plurality of fins 31 and a base 32 for improving the cooling efficiency. The heatsink 30 is also formed with a receptacle groove 33 for mounting.

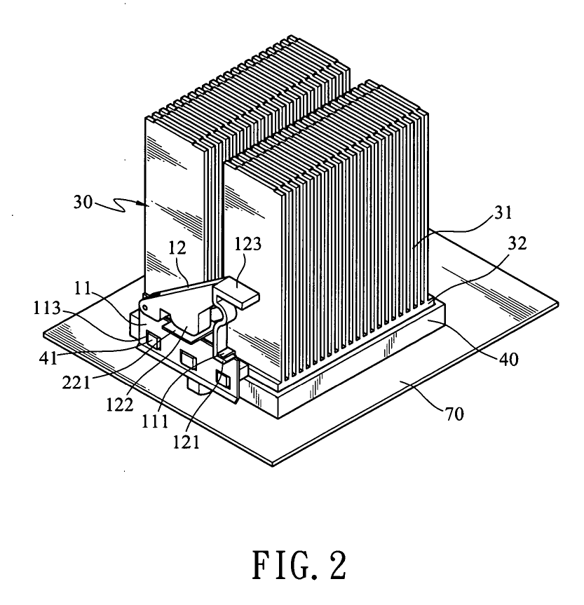

As shown in FIG. 1 and FIG. 2, the exploded view and assembly view of a first embodiment of the invention, the heatsink clamper according to the invention includes a buckle piece 10 and a main body 20. The buckle piece 10 is composed of a latch member 11 and a press member 12. The latch member 11 is buckled to a side of the seat 40. It includes a latch portion 111, a raised end 112 and buckle holes 113. The buckle holes 113 are correspondent to the fastening portions 41 on a side of the seat 40 for fastening the buckle piece 10 to the side of the seat 40. One end of press member 12 is pivoted to an end of the latch member 11. Another end of the latch member 11 includes the latch portion 111 correspondent to a latch end 121 of the press member 12. The press member 12 also includes a pressing end 122 at an appropriate position. A lever end 123 is located in the same side of the latch end 121, and capable of moving the latch end 121 engaged with latch portion 111. The main body 20 includes a buckle 21 and a pressing arm 22. The buckle 21 is buckled to another side of the seat 40. The buckle 21 includes buckle holes 211 corresponding to the fastening portions 41 on a side of the seat 40 so as to buckle on the side of the seat 40. The pressing arm 22 passes through the receptacle groove 33, and includes a pressed portion 221. The pressed portion 221 includes a hole 2211 corresponding to the raised end 112 for passing through and moving relatively. Further, lever the press member 12 to press the pressing end 122 on the pressed portion 221, and move the latch end 121 locked in the latch portion 111. Simultaneously, the pressing arm 22 is deformed to provide a downward pressure to the heatsink 30 via the receptacle groove 33, and firmly assemble the heatsink 30 to the central processing unit 50.

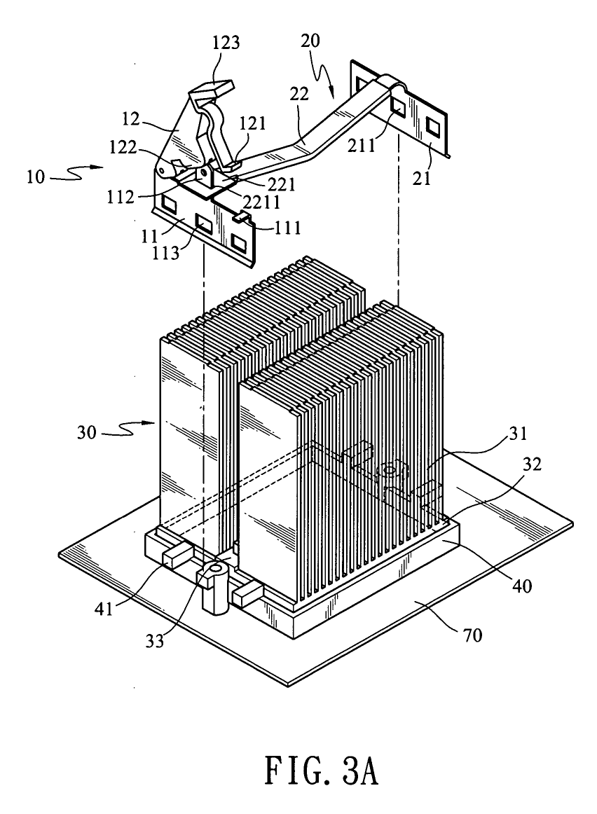

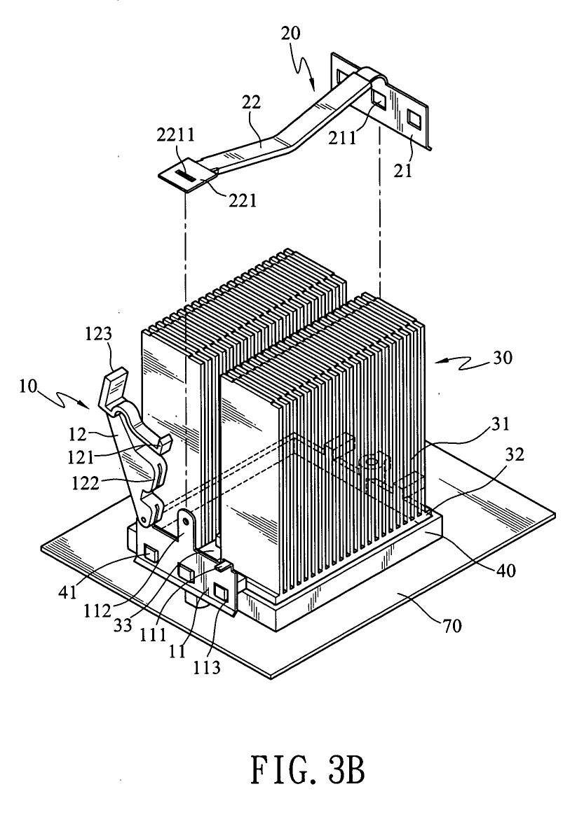

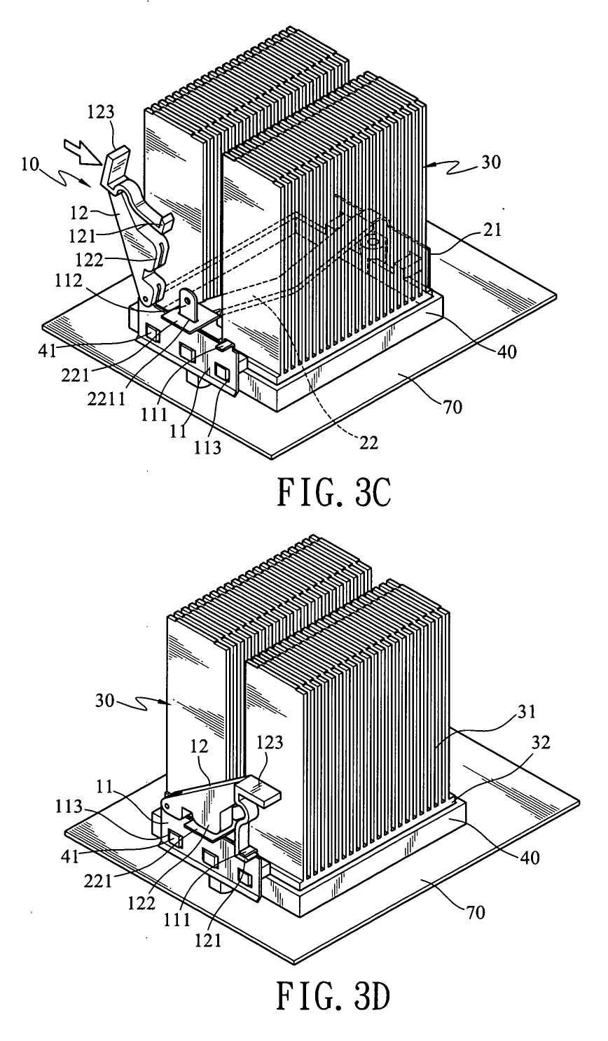

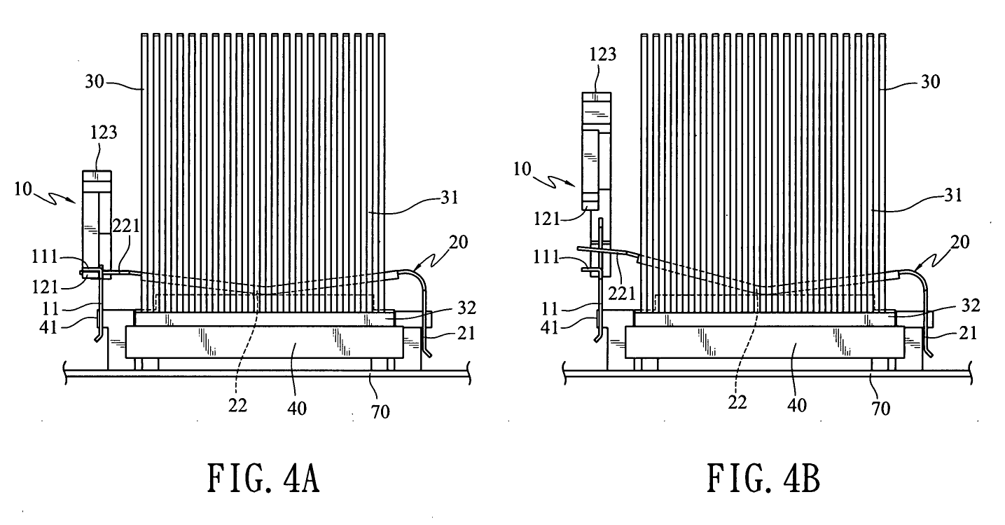

FIGS. 3A, 3B, 3C, and 3D illustrate the sequential views of assembling a first embodiment of the invention. Firstly, fit the buckle holes 113 of the buckle piece 10 to fastening portions 41 on a side of the seat 40. Then, fit the buckle holes 211 of the buckle 21 to the fastening portions 41 on another side of the seat 40. Thus the pressing arm 22 passes through the receptacle groove 33 of the heatsink 30, and the hole 2211 of the pressed portion 221 also passes through the raised end 112 and relatively movable. Then, lever the press member 12 to press the pressing end 122 of the press member 12 on the pressed portion 221, and move the latch end 121 into the latch portion 111 through resilience of the lever end 123 so as to finish the heatsink clamper assembly that the heatsink 30 is stably assembled to the central processing unit 50. The pressing arm 22 is deformed to provide a downward force to press the receptacle groove 33 of the heatsink 30 and firmly mount the heatsink 30 on the central processing unit 50. FIGS. 4A and 4B respectively illustrate the conditions of the pressing arm 22 in the first embodiment of the invention that presses and does not press the heatsink 30.

Similarly with a reverse sequence of FIGS. 3A, 3B, 3C and 3D, when disassembling the headsink clamper of the first embodiment of the invention, first press the lever end 123 to release the latch end 121 from the latch portion 111. Then, the pressing end 122 is free from the pressed portion 221, and the pressing arm 22 retrieves the primary form and no longer presses the receptacle groove 33 of the heatsink 30. Further, remove the pressed portion 221 of the pressing arm 22 from the buckle piece 10 by releasing the hole 2211 from the raised end 112, and remove the main body 20 from the receptacle groove 33, and releases the buckle holes 211 of the buckle 21 from the fastening portions 41, so that the main body 20 is removed from one side of the seat 40. Finally, remove the buckle piece 10 from the seat 40 by releasing the buckle hole 113 from the fastening portions 41 at the other side of the seat 40, and complete the disassembling.

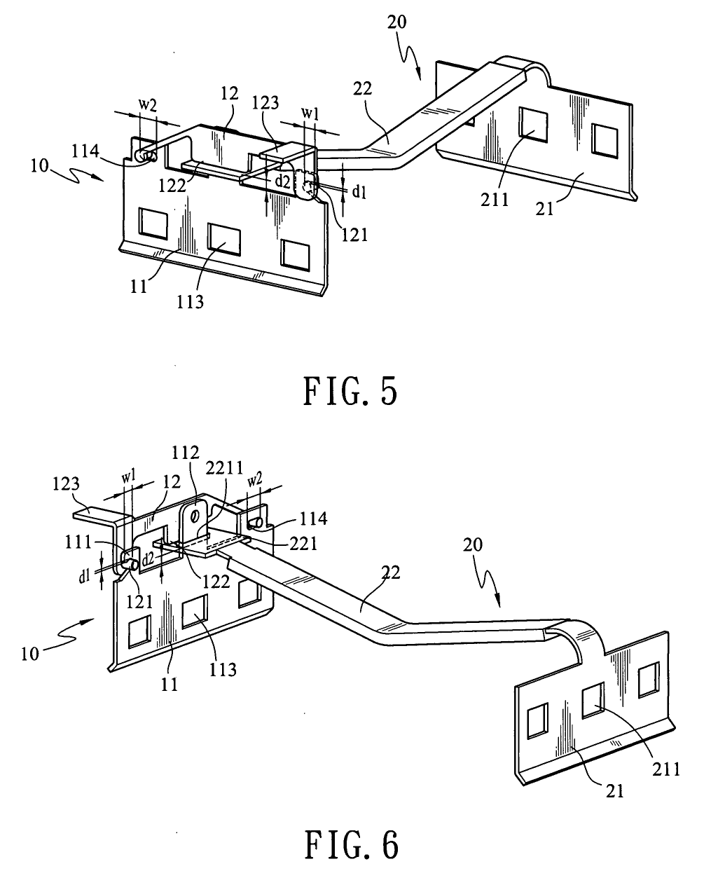

FIG. 5 shows an exploded view of a second embodiment of the invention. The seat 40 is a frame encircling a space to receive a hot element, such as a central processing unit 50, of an electronic device. The central processing unit 50 is connected through connectors 60 to a circuit board 70. The seat 40 is formed with a plurality of fastening portions 41. The heatsink 30 includes a plurality of fins 31 and a base 32 for improving cooling efficiency. The heatsink 30 is also formed with a receptacle groove 33 for mounting.

As shown in FIG. 5 and FIG. 6, two assembly views in different angles of a second embodiment of the invention, the heatsink clamper according to the invention includes a buckle piece 10 and a main body 20. The buckle piece 10 is composed of a latch member 11 and a press member 12. The latch member 11 is buckled to a side of the seat 40. It includes a latch portion 111, a raised end 112, buckle holes 113 and a pivot hole 114. The latch portion 111 is formed with a hook having a depth d1 and a width w1. The buckle holes 113 are correspondent to the fastening portions 41 on a side of the seat 40 for fastening the buckle piece 10 to the side of the seat 40. One end of press member 12 is pivoted to an end of the latch member 11 on the pivot hole 114. The pivot hole 114 is a slot having a width w2 larger than the width w1 of the hook of the latch portion 111. Another end of the latch member 11 includes the latch portion 111 corresponding to a latch end 121 of the press member 12. The press member 12 also includes a pressing end 122 at an appropriate position. A lever end 123 is located in the same side of the latch end 121, and capable of moving the latch end 121 engaged with latch portion 111. The main body 20 includes a buckle 21 and a pressing arm 22. The buckle 21 is buckled to another side of the seat 40. The buckle 21 includes buckle holes 211 corresponding to the fastening portions 41 on a side of the seat 40 so as to buckle on the side of the seat 40. The pressing arm 22 passes through the receptacle groove 33, and includes a pressed portion 221. The pressed portion 221 includes a hole 2211 corresponding to the raised end 112 for passing through and moving relatively. Further, lever the press member 12 to press the pressing end 122 on the pressed portion 221, and move the latch end 121 locked in the latch portion 111. Simultaneously, the pressing arm 22 is deformed to provide a downward pressure to the heatsink 30 via the receptacle groove 33, and firmly assemble the heatsink 30 to the central processing unit 50. When the pressing arm 22 is deformed, the bottom of raised end 112 remains a depth d2 from the pressed portion 221. The depth d2 is larger than the hook depth d1 of the latch portion 111.

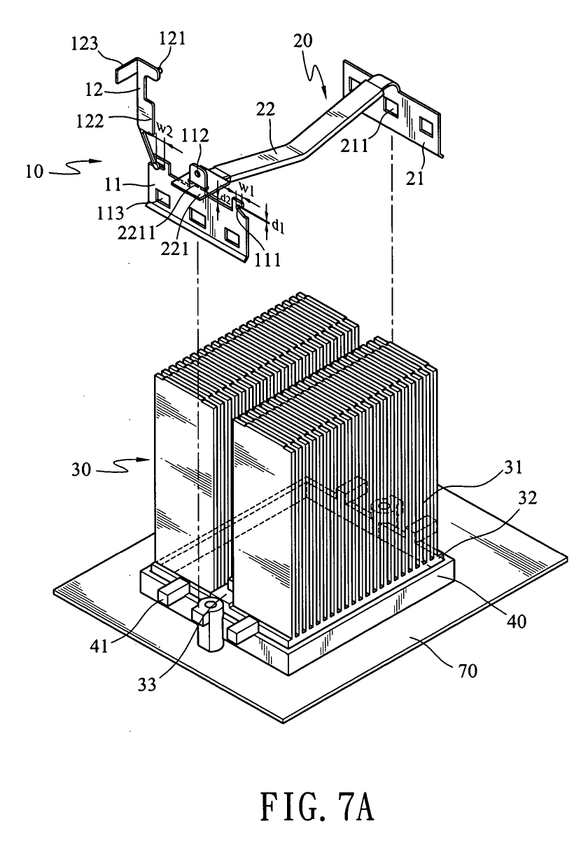

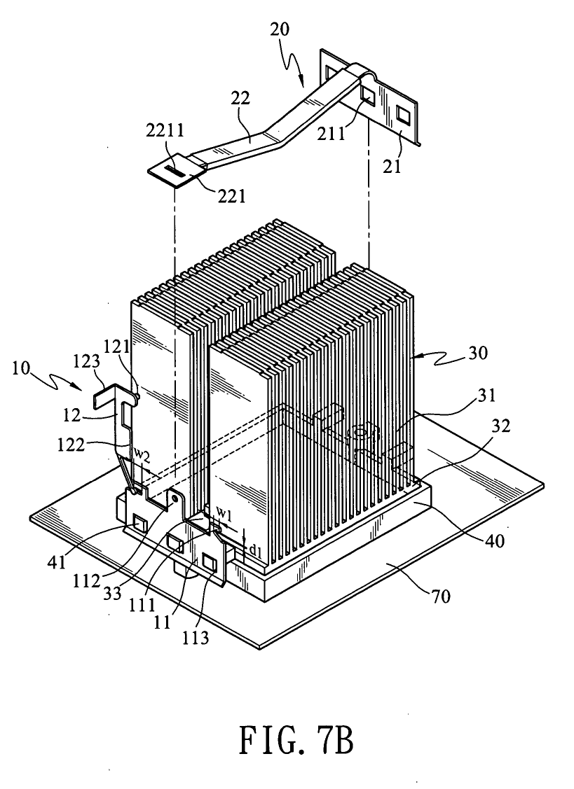

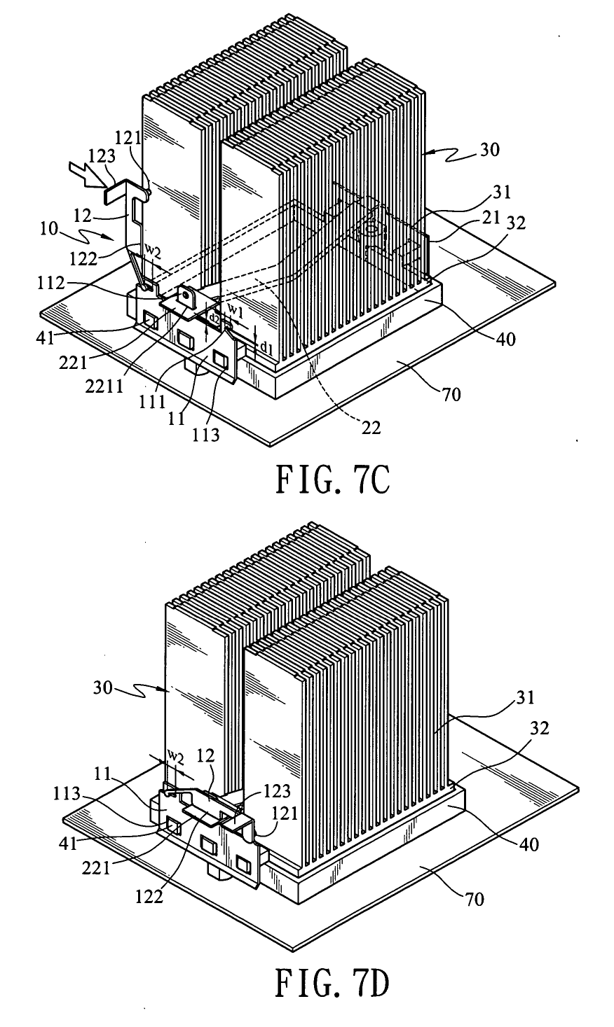

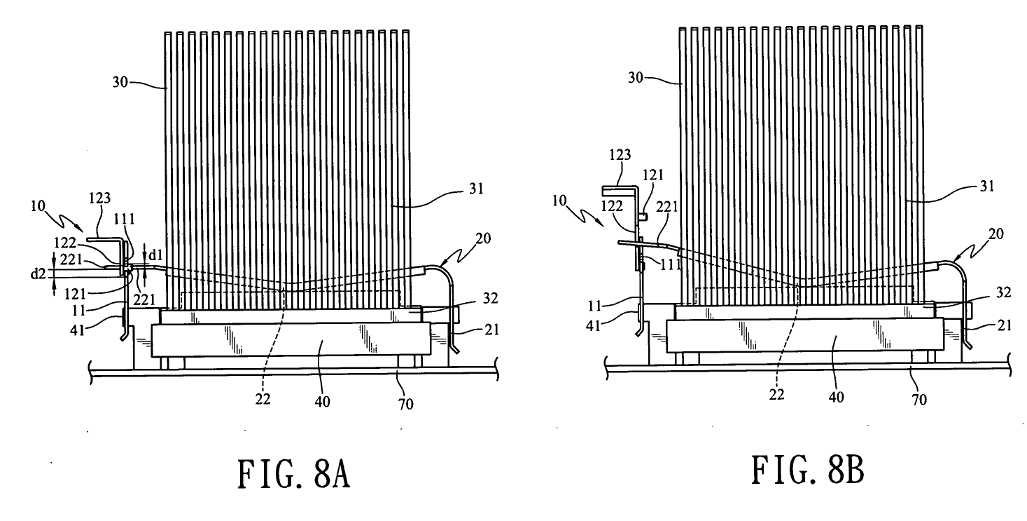

FIGS. 7A, 7B, 7C, and 7D illustrate the sequential views of assembling a second embodiment of the invention. Firstly, fit the buckle holes 113 of the buckle piece 10 to fastening portions 41 on a side of the seat 40. Then, fit the buckle holes 211 of the buckle 21 to the fastening portions 41 on another side of the seat 40. Thus the pressing arm 22 passes through the receptacle groove 33 of the heatsink 30, and the hole 2211 of the pressed portion 221 also passes through the raised end 112 and relatively movable. Then, lever the press member 12 to press the pressing end 122 of the press member 12 on the pressed portion 221, and move the latch end 121 into the latch portion 111 through resilience of the lever end 123 so as to finish the heatsink clamper assembly that the heatsink 30 is stably assembled to the central processing unit 50. The pressing arm 22 is deformed to provide a downward force to press the receptacle groove 33 of the heatsink 30 and firmly mount the heatsink 30 on the central processing unit 50. FIGS. 8A and 8B respectively illustrate the conditions of the pressing arm 22 in the second embodiment of the invention that presses and does not press the heatsink 30.

Similarly with a reverse sequence of FIGS. 7A, 7B, 7C and 7D, when disassembling the headsink clamper of the second embodiment of the invention, first press the lever end 123 to release the latch end 121 from the latch portion 111. Because the depth d2 from the bottom of raised end 112 to the pressed portion 221 is larger than the hook depth d1 of the latch portion 111, and the width w2 of the pivot hole 114 is larger than the width w1 of the latch portion 111, the lever end 123 can be freely pressed down to release the latch end 121 from the latch portion 111. Then, the pressing end 122 is free from the pressed portion 221, and the pressing arm 22 retrieves the primary form and no longer presses the receptacle groove 33 of the heatsink 30. Further, remove the pressed portion 221 of the pressing arm 22 from the buckle piece 10 by releasing the hole 2211 from the raised end 112, and remove the main body 20 from the receptacle groove 33, and releases the buckle holes 211 of the buckle 21 from the fastening portions 41, so that the main body 20 is removed from one side of the seat 40. Finally, remove the buckle piece 10 from the seat 40 by releasing the buckle hole 113 from the fastening portions 41 at the other side of the seat 40, and complete the disassembling.

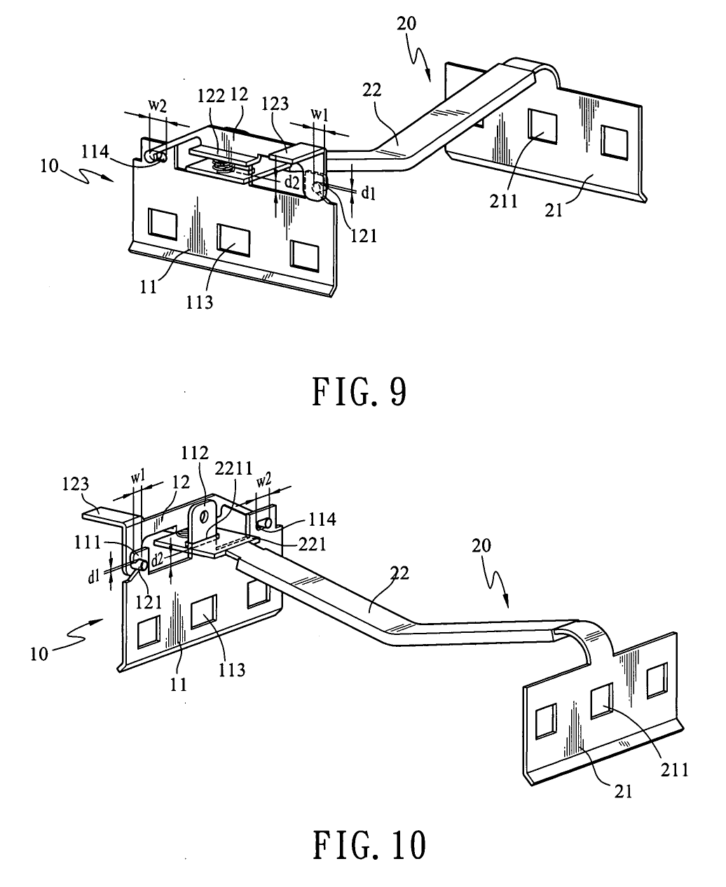

FIG. 9 shows an exploded view of a third embodiment of the invention. The seat 40 is a frame encircling a space to receive a hot element, such as a central processing unit 50, of an electronic device. The central processing unit 50 is connected through connectors 60 to a circuit board 70. The seat 40 is formed with a plurality of fastening portions 41. The heatsink 30 includes a plurality of fins 31 and a base 32 for improving cooling efficiency. The heatsink 30 is also formed with a receptacle groove 33 for mounting.

As shown in FIG. 9 and FIG. 10, two assembly views in different angles of a third embodiment of the invention, the heatsink clamper according to the invention includes a buckle piece 10 and a main body 20. The buckle piece 10 is composed of a latch member 11 and a press member 12. The latch member 11 is buckled to a side of the seat 40. It includes a latch portion 111, a raised end 112, buckle holes 113 and a pivot hole 114. The latch portion 111 is formed with a hook having a depth d1 and a width w1. The buckle holes 113 are correspondent to the fastening portions 41 on a side of the seat 40 for fastening the buckle piece 10 to the side of the seat 40. One end of press member 12 is pivoted to an end of the latch member 11 on the pivot hole 114. The pivot hole 114 is a slot having a width w2 larger than the width w1 of the hook of the latch portion 111. Another end of the latch member 11 includes the latch portion 111 corresponding to a latch end 121 of the press member 12. The press member 12 also includes a pressing end 122 at an appropriate position. A resilient member 1221 is mounted on the pressing end 122. A lever end 123 is located in the same side of the latch end 121, and capable of moving the latch end 121 engaged with latch portion 111. The main body 20 includes a buckle 21 and a pressing arm 22. The buckle 21 is buckled to another side of the seat 40. The buckle 21 includes buckle holes 211 corresponding to the fastening portions 41 on a side of the seat 40 so as to buckle on the side of the seat 40. The pressing arm 22 passes through the receptacle groove 33, and includes a pressed portion 221. The pressed portion 221 corresponding to the resilient member 1221 includes a hole 2211 corresponding to the raised end 112 for passing through and moving relatively. Further, lever the press member 12 to press the pressing end 122 on the pressed portion 221, and move the latch end 121 locked in the latch portion 111. Simultaneously, the pressing arm 22 is deformed to provide a downward pressure to the heatsink 30 via the receptacle groove 33, and firmly assemble the heatsink 30 to the central processing unit 50. When the pressing arm 22 is deformed, the bottom of raised end 112 remains a depth d2 from the pressed portion 221. The depth d2 is larger than the hook depth d1 of the latch portion 111.

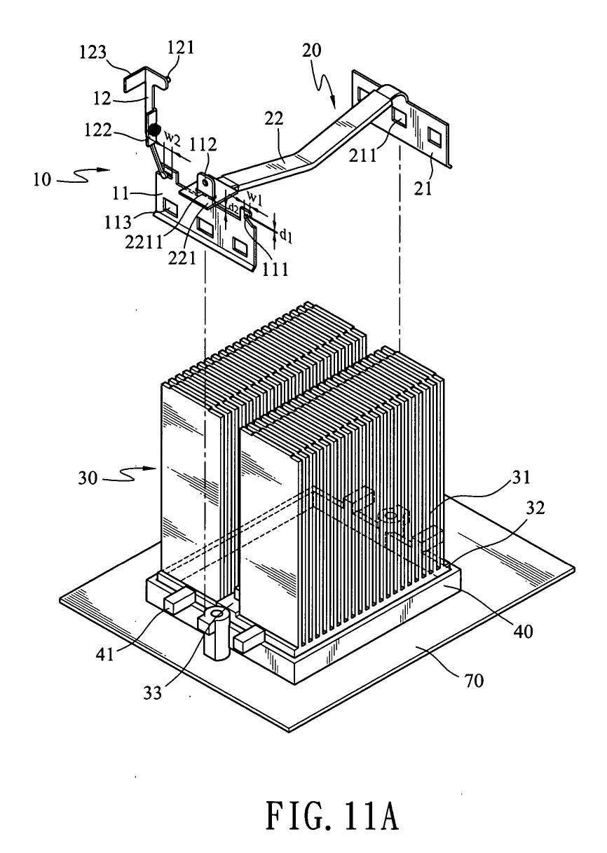

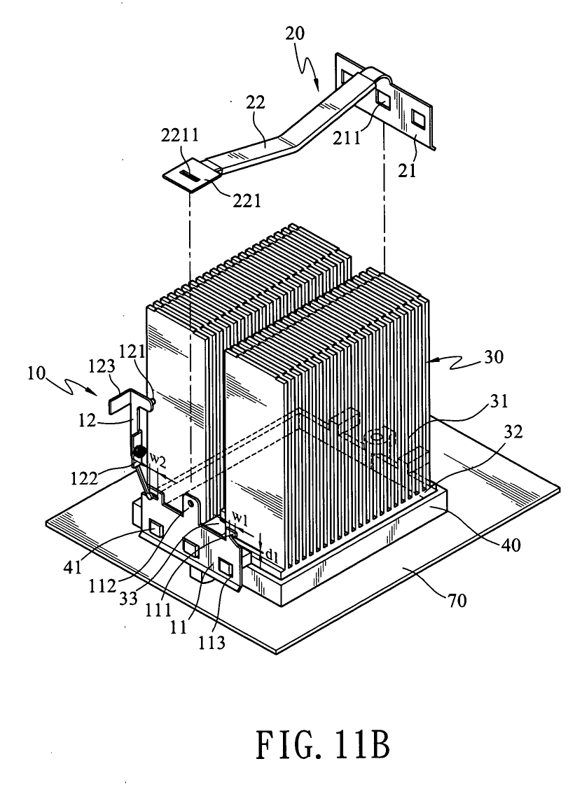

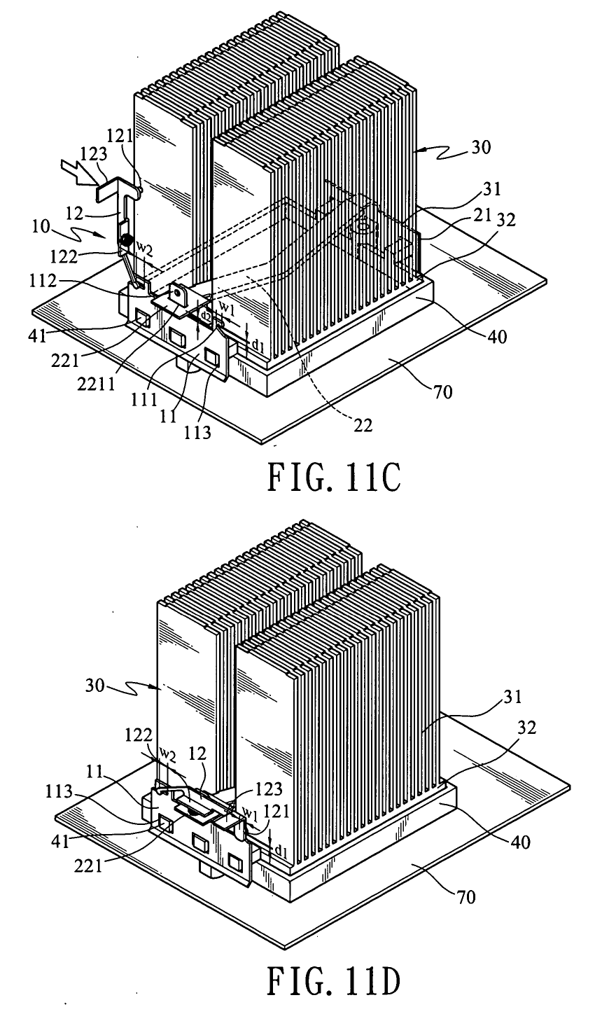

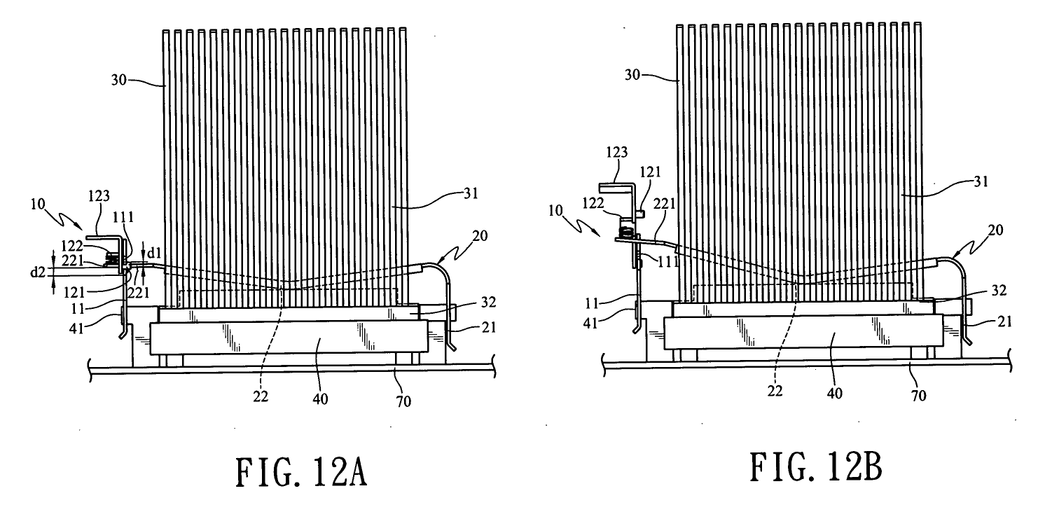

FIGS. 11A, 11B, 11C, and 11D illustrate the sequential views of assembling a third embodiment of the invention. Firstly, fit the buckle holes 113 of the buckle piece 10 to fastening portions 41 on a side of the seat 40. Then, fit the buckle holes 211 of the buckle 21 to the fastening portions 41 on another side of the seat 40. Thus the pressing arm 22 passes through the receptacle groove 33 of the heatsink 30, and the hole 2211 of the pressed portion 221 also passes through the raised end 112 and relatively movable. Then, lever the press member 12 to press the pressing end 122 of the press member 12 on the pressed portion 221 against the force of the resilient member 1211, and move the latch end 121 into the latch portion 111 so as to finish the heatsink clamper assembly that the heatsink 30 is stably assembled to the central processing unit 50. The pressing arm 22 is deformed to provide a downward force to press the receptacle groove 33 of the heatsink 30 and firmly mount the heatsink 30 on the central processing unit 50. FIGS. 12A and 12B respectively illustrate the conditions of the pressing arm 22 in the third embodiment of the invention that presses and does not press the heatsink 30.

Similarly with a reverse sequence of FIGS. 11A, 11B, 11C and 11D, when disassembling the headsink clamper of the third embodiment of the invention, first press the lever end 123 to release the latch end 121 from the latch portion 111. Because the depth d2 from the bottom of raised end 112 to the pressed portion 221 is larger than the hook depth d1 of the latch portion 111, and the width w2 of the pivot hole 114 is larger than the width w1 of the latch portion 111, the lever end 123 can be freely pressed down to release the latch end 121 from the latch portion 111. Then, the pressing end 122 is free from the pressed portion 221 by force of the compressed resilient member 1221, and the pressing arm 22 retrieves the primary form and no longer presses the receptacle groove 33 of the heatsink 30. Further, remove the pressed portion 221 of the pressing arm 22 from the buckle piece 10 by releasing the hole 2211 from the raised end 112, and remove the main body 20 from the receptacle groove 33, and releases the buckle holes 211 of the buckle 21 from the fastening portions 41, so that the main body 20 is removed from one side of the seat 40. Finally, remove the buckle piece 10 from the seat 40 by releasing the buckle hole 113 from the fastening portions 41 at the other side of the seat 40, and complete the disassembling.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims

What is claimed is:

1. A clamper for fixing a heatsink on a hot element of an electronic device, comprising:
a buckle piece, having a latch member and a press member, said latch member is buckled to a side of a seat that mounts said heatsink and said hot element, said latch member comprises a latch portion and a raised end, one end of said press member is pivoted on an end of said latch member, another end of said press member comprises a latch end correspondent to said latch portion of said latch member; and
a main body, having a buckle and a pressing arm linked together, said buckle is latched to another side of said seat, said pressing arm comprises a hole correspondent to said raised end for passing through said raised end and moving relatively, by pressing said press member to move said latch end into said latch portion, said pressing arm is pressed and deformed to provide a pressure to said heatsink through a receptacle groove and firmly fix said heatsink to said hot element of said electronic device.

2. The clamper for fixing a heatsink according to claim 1, wherein said main body further comprises a pressed portion, on which said hole is formed.

3. The clamper for fixing a heatsink according to claim 2, wherein said press member comprises a pressing end, which further comprises a resilient member correspondent to said pressed portion.

4. The clamper for fixing a heatsink according to claim 1, wherein said latch member further comprises at least a buckle hole.

5. The clamper for fixing a heatsink according to claim 1, wherein said buckle further comprises at least a buckle hole.

6. The clamper for fixing a heatsink according to claim 1, wherein said latch member comprises a pivot hole having a width larger than a width of said latch portion, a depth from a bottom of said raised end to said pressed portion is larger than a depth of said latch portion.
